(19) United States
(12) Patent Application Publication
(10) Pub. No.: US 2023/0108567 A1
(43) Pub. Date: Apr. 6, 2023

(54) ADHESIVE COMPOSITION AND FILM-LIKE ADHESIVE, AND SEMICONDUCTOR PACKAGE USING FILM-LIKE ADHESIVE AND PRODUCING METHOD THEREOF

(71) Applicant: FURUKAWA ELECTRIC CO., LTD., Tokyo (JP)

(72) Inventor: Minoru MORITA, Tokyo (JP)

(73) Assignee: FURUKAWA ELECTRIC CO., LTD., Tokyo (JP)

(21) Appl. No.: 17/970,402

(22) Filed: Oct. 20, 2022

Related U.S. Application Data
(63) Continuation of application No. PCT/JP2021/018947, filed on May 19, 2021.

(30) Foreign Application Priority Data
Jul. 30, 2020 (JP) 2020-129493

(51) Int. Cl. C09D 163/00

(52) U.S. Cl. CPC C09D 163/00

(57) ABSTRACT

An adhesive composition containing an epoxy resin (A), an epoxy resin curing agent (B), a phenoxy resin (C), and an inorganic filler (D), in which the phenoxy resin (C) has an elastic modulus of 500 MPa or more at 25° C., a proportion of the phenoxy resin (C) in a total content of the epoxy resin (A) and the phenoxy resin (C) is 10 to 60 mass%, a nanoindentation hardness at 25° C. of a film-like adhesive before curing formed using the adhesive composition is 0.10 MPa or more, and the Young’s modulus at 25° C. of a film-like adhesive before curing formed using the adhesive composition is 100 MPa or more;
a film-like adhesive using the adhesive composition; and
a semiconductor package using the film-like adhesive and a producing method thereof.

### CROSS REFERENCE TO RELATED APPLICATIONS

This application is a Continuation of PCT International Application No. PCT/JP2021/018947 filed on May 19, 2021, which claims priority under 35 U.S.C. § 119 (a) to Japanese Patent Application No. 2020-129493 filed in Japan on Jul. 30, 2020. Each of the above applications is hereby expressly incorporated by reference, in its entirely, into the present application.

### FIELD OF THE INVENTION

The present invention relates to an adhesive composition and a film-like adhesive, and a semiconductor package using the film-like adhesive and a producing method thereof.

### BACKGROUND OF THE INVENTION

Stacked MCPs (Multi Chip Package) in which semiconductor chips are multistacked have recently been widely spread. Such stacked MCPs are mounted on memory packages for mobile phones or portable audio devices. Further, along with multi-functionality of mobile phones and the like, high densification and high integration of the package have also been advanced. Along with such advance, multistacking of the semiconductor chips has been advanced.

Film-like adhesives (die attach films) have been used for bonding a wiring board and a semiconductor chip or bonding semiconductor chips (that is, die attach) in the production process of such a memory package. This film-like adhesive is required to have sufficient adhesiveness. In addition, along with the multistacking of the semiconductor chips, thinning of a film-like adhesive is also required.

Conventionally, as a material that can be used as a so-called thin film-like adhesive, for example, Patent Document 1 describes a film roll for manufacturing a semiconductor device in which an adhesive layer containing an acrylic acid ester-based polymer, a polyfunctional isocyanate-based crosslinking agent, an epoxy resin, a phenol resin, and silica and having a Shore A hardness specified is provided.

In addition, Patent Document 2 describes a heat-dissipating film-like adhesive containing two or more kinds of thermally conductive fillers having different Mohs hardness and having a blade wear amount of 50 µm/m or less in a dicing step, the film-like adhesive containing an epoxy resin, an epoxy resin curing agent, and a phenoxy resin.

### CITATION LIST

### Patent Literatures

Patent Literature 1: Japanese Patent No. 5322609
Patent Literature 2: JP-A-2019-21829 (“JP-A” means an unexamined published Japanese patent application)

### SUMMARY OF THE INVENTION

### Technical Problem

Usually, when a film-like adhesive is used, a semiconductor wafer to which the film-like adhesive is bonded is diced with a dicing tape as a base to be divided into semiconductor chips. Thereafter, the divided semiconductor chip with the film-like adhesive undergoes a pickup step of peeling off from the dicing tape with a jig such as a needle or a slider from the lower portion of the dicing tape, and is thermocompression-bonded to the surface of the wiring board or the surface of the semiconductor element.

Since the surface of the wiring board and the surface of the semiconductor element are not necessarily in a smooth surface state, air may be entrained in the interface between the film-like adhesive and the adherend during thermocompression bonding. The entrained air (voids) may not only lower the adhesive force after thermal curing but also cause a decrease in heat dissipation and the like.

In addition, in the film-like adhesive, a jig trace such as a needle or a slider in the pickup step may remain on the surface of the film-like adhesive. Such a jig mark becomes a void when the film-like adhesive is thermocompression-bonded, and may cause problems such as a decrease in adhesive force described above. The problem that the jig mark remains and becomes a void becomes more apparent as the film-like adhesive is thinned (for example, less than 20 µm).

The present invention has been made in view of the problems of the prior art, and provides a film-like adhesive having good die attachability, in which a jig mark in a pickup step hardly remains on a surface of the film-like adhesive even when the film-like adhesive is a thin film, and formation of voids can be suppressed during mounting, and an adhesive composition suitable for obtaining the same. Further, the present invention provides a semiconductor package using the film-like adhesive and a method of producing the same.

### Solution to Problem

As a result of intensive studies in view of the above problems, the present inventors have found that the above problems can be solved by adopting a combination of an epoxy resin, an epoxy resin curing agent, a phenoxy resin, and an inorganic filler as a raw material of a film-like adhesive, and then using a phenoxy resin exhibiting a certain elastic modulus or more as the phenoxy resin, setting the content of the phenoxy resin to a certain value or more in the total content of the epoxy resin and the phenoxy resin, and controlling the nanoindentation hardness and the Young’s modulus before curing to be a certain value or more.

The present invention is based on these findings, and after further investigation, has been completed.

The above problems of the present invention have been solved by the following means.
[1] An adhesive composition, containing:
   an epoxy resin (A);
   an epoxy resin curing agent (B);
   a phenoxy resin (C); and
   an inorganic filler (D),
      wherein the phenoxy resin (C) has an elastic modulus of 500 MPa or more at 25° C.,
      wherein a proportion of the phenoxy resin (C) in a total content of the epoxy resin (A) and the phenoxy resin (C) is 10 to 60 mass%, and
      wherein a nanoindentation hardness at 25° C. of a film-like adhesive before curing formed using the adhesive composition is 0.10 MPa or more, and the Young’s modulus at 25° C. of a film-like adhesive before curing formed using the adhesive composition is 100 MPa or more.
[2] The adhesive composition described in [1],
   wherein the inorganic filler (D) has an average particle diameter (d50) of 0.01 to 5.0 µm, and
   wherein a proportion of the inorganic filler (D) in a total content of the epoxy resin (A), the epoxy resin curing agent (B), the phenoxy resin (C), and the inorganic filler (D) is 5 to 70 vol%.
[3] The adhesive composition described in [2], wherein the inorganic filler (D) contains an inorganic filler having a Mohs hardness of 2 or more.
[4] The adhesive composition described in any one of [1] to [3], wherein when a film-like adhesive before curing formed using the adhesive composition is heated at a temperature elevation rate of 5° C./min from 25° C., a melt viscosity at 120° C. is in a range of 100 to 10000 Pas.
[5] A film-like adhesive obtained from the adhesive composition described in any one of [1] to [4].
[6] The film-like adhesive described in [5], which has a thickness of 1 to 60 µm.
[7] A method of producing a semiconductor package, containing:
   a first step of providing an adhesive layer by thermocompression bonding the film-like adhesive described in [5] or [6] to a back surface of a semiconductor wafer in which at least one semiconductor circuit is formed on a surface, and providing a dicing tape with the adhesive layer interposed between the back surface and the dicing tape;
   a second step of dicing the semiconductor wafer and the adhesive layer simultaneously to obtain a semiconductor chip with an adhesive layer, the semiconductor chip with an adhesive layer including the semiconductor wafer and the adhesive layer on the dicing tape;
   a third step of removing the dicing tape from the adhesive layer and thermocompression bonding the semiconductor chip with an adhesive layer and a wiring board with the adhesive layer; and
   a fourth step of thermally curing the adhesive layer.
[8] A semiconductor package wherein a semiconductor chip and a wiring board, or semiconductor chips are bonded with a thermally curable component of the film-like adhesive described in [5] or [6].

The numerical ranges indicated with the use of the term “to” in the present invention refer to ranges including the numerical values before and after the term “to” respectively as the lower limit and the upper limit.

In the present invention, (meth)acryl means either or both of acryl and methacryl. The same applies to (meth)acrylate.

### Advantageous Effects of Invention

The film-like adhesive of the present invention is a film-like adhesive having good die attachability, in which a jig mark in a pickup step hardly remains on a surface of the film-like adhesive, and formation of voids can be suppressed during mounting.

The adhesive composition of the present invention is suitable for providing the film-like adhesive.

According to the producing method of the present invention, a semiconductor package can be produced using the film-like adhesive.

### BRIEF DESCRIPTION OF DRAWINGS

FIG. 1 is a schematic longitudinal cross-sectional view illustrating a preferred embodiment of a first step of a method of producing a semiconductor package of the present invention.

FIG. 2 is a schematic longitudinal cross-sectional view illustrating a preferred embodiment of a second step of a method of producing a semiconductor package of the present invention.

FIG. 3 is a schematic longitudinal cross-sectional view illustrating a preferred embodiment of a third step of a method of producing a semiconductor package of the present invention.

FIG. 4 is a schematic longitudinal cross-sectional view illustrating a preferred embodiment of a step of connecting a bonding wire of a method of producing a semiconductor package of the present invention.

FIG. 5 is a schematic longitudinal cross-sectional view illustrating an example of an embodiment of multistacking of a method of producing a semiconductor package of the present invention.

FIG. 6 is a schematic longitudinal cross-sectional view illustrating an example of an embodiment of another multistacking of a method of producing a semiconductor package of the present invention.

FIG. 7 is a schematic longitudinal cross-sectional view illustrating a preferred embodiment of a semiconductor package produced by a method of producing a semiconductor package of the present invention.

### DESCRIPTION OF EMBODIMENTS

### Adhesive Composition and Film-Like Adhesive

The adhesive composition of the present invention can be suitably used for forming a film-like adhesive.

The adhesive composition of the present invention contains an epoxy resin (A), an epoxy resin curing agent (B), a phenoxy resin (C), and an inorganic filler (D),
the phenoxy resin (C) has an elastic modulus of 500 MPa or more at 25° C.,
the proportion of the phenoxy resin (C) in a total content of the epoxy resin (A) and the phenoxy resin (C) is 10 to 60 mass%, and
the nanoindentation hardness at 25° C. of the film-like adhesive before curing formed using the adhesive composition is 0.10 MPa or more, and the Young’s modulus at 25° C. of a film-like adhesive before curing formed using the adhesive composition is 100 MPa or more.

As used herein, the film-like adhesive before curing refers to one in which the epoxy resin (A) is in a state before thermal curing. The film-like adhesive before thermal curing specifically means a film-like adhesive which is not exposed to a temperature condition at 25° C. or higher after formation of the film-like adhesive. On the other hand, the film-like adhesive after curing refers to one in which the epoxy resin (A) is thermally cured. The above description is intended to clarify the characteristics of the adhesive composition of the present invention, and the film-like adhesive of the present invention is not limited to one that is not exposed to a temperature condition at 25° C. or higher.

Further, when the nanoindentation hardness and the Young’s modulus are measured, exposure to a temperature that does not substantially cure is not hindered.

The nanoindentation hardness at 25° C. of the film-like adhesive before curing is 0.10 MPa or more from the viewpoint of enhancing die attachability while suppressing formation of a jig mark. The nanoindentation hardness is preferably 0.10 to 5.00 MPa, more preferably 0.20 to 3.00 MPa, further preferably 1.00 to 2.50 MPa, and particularly preferably 1.40 to 2.20 MPa. The nanoindentation hardness is measured by the method described in Examples in accordance with ISO 14577 (2015 edition). The nanoindentation hardness can be controlled by adjusting the content of each resin component, the elastic modulus of the phenoxy resin (C), the content and type of the inorganic filler, and the like.

The Young’s modulus at 25° C. of the film-like adhesive before curing is 100 MPa or more from the viewpoint of enhancing the die attachability while suppressing the formation of the jig mark. The Young’s modulus is preferably 100 to 5000 MPa, more preferably 200 to 3000 MPa, and still more preferably 1000 to 2000 MPa. The Young’s modulus can be measured by the method described in Examples. The Young’s modulus can be controlled by adjusting the content of each resin component, the elastic modulus of the phenoxy resin (C), the content and type of the inorganic filler, and the like.

The values of the nanoindentation hardness and the Young’s modulus are values assuming a case where the film-like adhesive before curing has a thickness of 100 µm, and the values of the nanoindentation hardness and the Young’s modulus can be determined by preparing a film-like adhesive having a thickness of 100 µm as in Examples described later.

Hereinafter, each component contained in the adhesive composition will be described.

### Epoxy Resin (A)

The epoxy resin (A) is a thermosetting resin having an epoxy group, and has an epoxy equivalent of 500 g/eq or less. The epoxy resin (A) may be liquid, solid, or semi-solid. The liquid in the present invention means that the softening point is less than 25° C. The solid means that the softening point is 60° C. or more. The semi-solid means that the softening point is between the softening point of the liquid and the softening point of the solid (25° C. or more and less than 60° C.). As the epoxy resin (A) used in the present invention, the softening point is preferably 100° C. or less from the viewpoint of obtaining a film-like adhesive that can reach low melt viscosity in a preferable temperature range (for example, 60 to 120° C.). Incidentally, in the present invention, the softening point is a value measured by the softening point test (ring and ball) method (measurement condition: in accordance with JIS-2817).

In the epoxy resin (A) used in the present invention, the epoxy equivalent is preferably 150 to 450 g/eq from the viewpoint of increasing the crosslinking density of a cured product, and as a result, increasing the contact ratio between blended inorganic fillers (D) and the contact area between inorganic fillers (D), thus providing higher thermal conductivity. Incidentally, in the present invention, the epoxy equivalent refers to the number of grams of a resin containing 1 gram equivalent of epoxy group (g/eq).

The mass average molecular weight of the epoxy resin (A) is usually preferably less than 10,000 and more preferably 5,000 or less. The lower limit is not particularly limited, but is practically 300 or more.

The mass average molecular weight is a value obtained by GPC (Gel Permeation Chromatography) analysis.

Examples of the skeleton of the epoxy resin (A) include a phenol novolac type, an orthocresol novolac type, a cresol novolac type, a dicyclopentadiene type, a biphenyl type, a fluorene bisphenol type, a triazine type, a naphthol type, a naphthalene diol type, a triphenylmethane type, a tetraphenyl type, a bisphenol A type, a bisphenol F type, a bisphenol AD type, a bisphenol S type, and a trimethylolmethane type. Among them, a triphenylmethane type, a bisphenol A type, a cresol novolac type, and an orthocresol novolac type are preferable from the viewpoint of being capable of obtaining a film-like adhesive having low resin crystallinity and good appearance.

The content of the epoxy resin (A) is preferably 3 to 70 parts by mass, preferably 3 to 30 parts by mass, and more preferably 5 to 30 parts by mass based on 100 parts by mass of the total content of components constituting the film-like adhesive (specifically, components other than a solvent) in the adhesive composition of the present invention. By setting the content within the above preferable range, it is possible to enhance die attachability while suppressing the formation of any jig mark. Meanwhile, by adjusting the content to the preferable upper limit or less, generation of oligomer components can be suppressed, and the state of the film (e.g., film tack property) is unlikely to be changed in the case of a small change in temperature.

### Epoxy Resin Curing Agent (B)

As the epoxy resin curing agent (B), optional curing agents such as amines, acid anhydrides, and polyhydric phenols can be used. In the present invention, a latent curing agent is preferably used from the viewpoint of having a low melt viscosity, and being capable of providing a film-like adhesive that exhibits curability at a high temperature more than a certain temperature, has rapid curability, and further has high storage stability that enables long-term storage at room temperature.

Examples of the latent curing agent include a dicyandiamide compound, an imidazole compound, a curing catalyst-complex polyhydric phenol compound, a hydrazide compound, a boron trifluoride-amine complex, an aminimide compound, a polyamine salt, and modified products or microcapsules thereof. They may be used singly, or in combination of two or more types thereof. Use of an imidazole compound is more preferable from the viewpoint of providing even better latency (properties of excellent stability at room temperature and exhibiting curability by heating) and providing a more rapid curing rate.

The content of the epoxy resin curing agent (B) based on 100 parts by mass of the epoxy resin (A) is preferably 0.5 to 100 parts by mass, more preferably 1 to 80 parts by mass, further preferably 2 to 50 parts by mass, and further preferably 4 to 20 parts by mass. Setting the content to the preferable lower limit or more can further reduce the curing time. On the other hand, setting the content to the preferable upper limit or less can suppress excessive remaining of the curing agent in the film-like adhesive. As a result, moisture absorption by the remaining curing agent can be suppressed, and thus the reliability of the semiconductor device can be improved.

### Phenoxy Resin (C)

The phenoxy resin (C) is a component that suppresses film tackiness at normal temperature (25° C.) and imparts film formation property (film formability) when a film-like adhesive is formed.

In the phenoxy resin (C), the elastic modulus at normal temperature (25° C.) is 500 MPa or more. The normal temperature (25° C.) elastic modulus of the phenoxy resin (C) is preferably 1000 MPa or more, more preferably 1500 MPa or more. The upper limit of the normal temperature (25° C.) elastic modulus is not particularly limited, but is preferably 2000 MPa or less. Use of the phenoxy resin having such an elastic modulus enables to achieve both suppression of a jig mark and die attachability at a higher level.

The normal temperature (25° C.) elastic modulus can be determined by the method described in examples described later. Incidentally, the elastic modulus at normal temperature (25° C.) in a case where the adhesive composition contains two or more kinds of phenoxy resins can be determined by using, as a phenoxy resin film for measurement of normal temperature elastic modulus in the method described in EXAMPLES described later, a film produced by blending the phenoxy resins at a mixing ratio for constituting the adhesive composition.

The mass average molecular weight of the phenoxy resin (C) is usually 10,000 or more. The upper limit is not particularly limited, but is practically 5,000,000 or less.

The mass average molecular weight of the phenoxy resin (C) is determined by GPC (Gel Permeation Chromatography) in terms of polystyrene.

The glass transition temperature (Tg) of the phenoxy resin (C) is preferably less than 120° C., more preferably less than 100° C., and more preferably less than 90° C. The lower limit is preferably 0° C. or higher and more preferably 10° C. or higher.

The glass transition temperature of the phenoxy resin (C) is a glass transition temperature measured by DSC at a temperature elevation rate of 0.1° C./min.

The adhesive composition contains at least one kind of phenoxy resin as the phenoxy resin (C).

Note that as used herein, the phenoxy resin (C) is one having an epoxy equivalent (mass of resin per equivalent of epoxy group) of more than 500 g/eq. Specifically, a resin having an epoxy equivalent of 500 g/eq or less even though having a phenoxy resin structure is classified as the epoxy resin (A).

The phenoxy resin (C) can be obtained by a reaction of a bisphenol or biphenol compound with epihalohydrin such as epichlorohydrin, or a reaction of liquid epoxy resin with a bisphenol or biphenol compound.

In any of the reactions, the bisphenol or biphenol compound is preferably a compound represented by the following Formula (A).

[Formula 1]

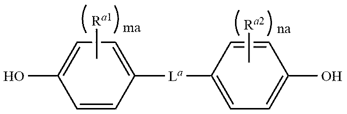

In Formula (A), L^{a} represents a single bond or divalent linking group, and R^{a1} and R^{a2} each independently represents a substituent. ma and na each independently represents an integer of 0 to 4.

In L^{a}, the divalent linking group is preferably an alkylene group, a phenylene group, —O—, —S—, —SO—, —SO₂—, or a group in which an alkylene group and a phenylene group are combined.

The number of carbon atoms of the alkylene group is preferably 1 to 10, more preferably 1 to 6, further preferably 1 to 3, particularly preferably 1 or 2, and most preferably 1.

The alkylene group is preferably —C(R^{α})(R^{β})—, and here, R^{α} and R^{β} each independently represent a hydrogen atom, an alkyl group, and an aryl group. R^{α} and R^{β} may be bonded to each other to form a ring. R^{α} and R^{β} are preferably a hydrogen atom or an alkyl group (for example, methyl, ethyl, isopropyl, n-propyl, n-butyl, isobutyl, hexyl, octyl, and 2-ethylhexyl). The alkylene group is, in particular, preferably —CH₂—, —CH(CH₃)—, or C(CH₃)₂—, more preferably —CH₂— or —CH(CH₃)—, and further preferably —CH₂—.

The number of carbon atoms of the phenylene group is preferably 6 to 12, more preferably 6 to 8, and even more preferably 6. Examples of the phenylene group include p-phenylene, m-phenylene, and o-phenylene, among which p-phenylene and m-phenylene are preferable.

The group in which an alkylene group and a phenylene group are combined is preferably an alkylene-phenylene-alkylene group, and more preferably -C(R^{α})(R^{β})-phenylene-C(R^{α})(R^{β})-.

The ring formed by bonding of R^{α} and R^{β} is preferably a 5- or 6-membered ring, more preferably a cyclopentane ring or a cyclohexane ring, and further preferably a cyclohexane ring.

L^{a} is preferably a single bond, an alkylene group, —O—, or —SO₂—; and more preferably an alkylene group.

R^{a1} and R^{a2} are preferably an alkyl group, an aryl group, an alkoxy group, an alkylthio group, or a halogen atom; more preferably an alkyl group, an aryl group, or a halogen atom; and further preferably an alkyl group.

ma and na are preferably 0 to 2, more preferably 0 or 1, and further preferably 0.

Examples of the bisphenol or biphenol compound include bisphenol A, bisphenol AD, bisphenol AP, bisphenol AF, bisphenol B, bisphenol BP, bisphenol C, bisphenol E, bisphenol F, bisphenol G, bisphenol M, bisphenol S, bisphenol P, bisphenol PH, bisphenol TMC, bisphenol Z, 4,4'-biphenol, 2,2'-dimethyl-4,4'-biphenol, 2,2',6,6'-tetramethyl-4,4'-biphenol, cardo skeleton type bisphenol, and the like. Bisphenol A, bisphenol AD, bisphenol C, bisphenol E, bisphenol F, and 4,4'-biphenol are preferable; bisphenol A, bisphenol E, and bisphenol F are more preferable; and bisphenol A is particularly preferable.

The liquid epoxy resin is preferably diglycidyl ether of an aliphatic diol compound, and is more preferably a compound represented by the following Formula (B).

[Formula 2]

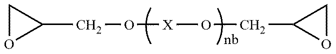

In Formula (B), X represents an alkylene group, and nb represents an integer of 1 to 10.

The number of carbon atoms of the alkylene group is preferably 2 to 10, more preferably 2 to 8, further preferably 3 to 8, particularly preferably 4 to 6, and most preferably 6.

Examples thereof include ethylene, propylene, butylene, pentylene, hexylene, and octylene. Ethylene, trimethylene, tetramethylene, pentamethylene, heptamethylene, hexamethylene, and octamethylene are preferable.

nb is preferably 1 to 6, more preferably 1 to 3, and further preferably 1.

Here, when nb is 2 to 10, X is preferably ethylene or propylene, and further preferably ethylene.

Examples of the aliphatic diol compound in diglycidyl ether include ethylene glycol, propylene glycol, diethylene glycol, triethylene glycol, polyethylene glycol, 1,3-propanediol, 1,4-butanediol, 1,5-heptanediol, 1,6-hexanediol, 1,7-pentanediol, and 1,8-octanediol.

As the phenoxy resin, one kind or two or more kinds of bisphenol or biphenol compounds can be used in the above reaction. Also, one kind or two or more kinds of aliphatic diol compounds can also be used. Examples thereof include a phenoxy resin obtained by reacting diglycidyl ether of 1,6-hexanediol with a mixture of bisphenol A and bisphenol F.

The phenoxy resin (C) in the present invention is preferably a phenoxy resin obtained by a reaction of a liquid epoxy resin with a bisphenol or biphenol compound, and more preferably a phenoxy resin having a repeating unit represented by the following Formula (I).

[Formula 3]

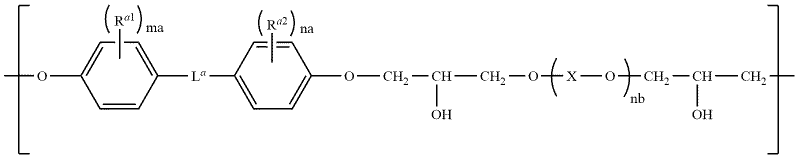

In the formula (I), L^{a}, R^{a1}, R^{a2}, ma, and na are synonymous with L^{a}, R^{a1}, R^{a2}, ma, and na in the formula (A), and the preferable ranges are also the same. X and nb have the same meanings as those in Formula (B), and the preferable ranges are also the same.

In the present invention, a polymer of bisphenol A and diglycidyl ether of 1,6-hexanediol is preferable among these substances.

Now, focus on the skeleton of the phenoxy resin, in the present invention, a bisphenol A type phenoxy resin or a bisphenol A/F type copolymerized phenoxy resin may be preferably used. In addition, a low-elastic high-heat-resistant phenoxy resin may be preferably used.

The mass average molecular weight of the phenoxy resin (C) is preferably 10,000 or larger and more preferably 10,000 to 100,000.

Further, the amount of epoxy group remaining in a small amount in the phenoxy resin (C) is preferably more than 5,000 g/eq in epoxy equivalent amount.

The glass transition temperature (Tg) of the phenoxy resin (C) is preferably less than 100° C., and more preferably less than 90° C. The lower limit is preferably 0° C. or higher and more preferably 10° C. or higher.

The phenoxy resin (C) may be synthesized by the above method, or a commercially available product may be used. Examples of the commercially available product include 1256 (bisphenol A type phenoxy resin, manufactured by Mitsubishi Chemical Corporation), YP-50 (bisphenol A type phenoxy resin, manufactured by NSCC Epoxy Manufacturing Co., Ltd.), YP-70 (bisphenol A/F type phenoxy resin, manufactured by NSCC Epoxy Manufacturing Co., Ltd.), FX-316 (bisphenol F type phenoxy resin, manufactured by NSCC Epoxy Manufacturing Co., Ltd.), FX-280S (cardo skeleton type phenoxy resin, manufactured by NSCC Epoxy Manufacturing Co., Ltd.), 4250 (bisphenol A type/F type phenoxy resin, manufactured by Mitsubishi Chemical Corporation), and FX-310 (low-elastic high-heat-resistant phenoxy resin, manufactured by NSCC Epoxy Manufacturing Co., Ltd.).

In the adhesive composition, the proportion of the phenoxy resin (C) in the total content of the epoxy resin (A) and the phenoxy resin (C) is 10 to 60 mass%, preferably 15 to 50 mass%, and preferably 18 to 45 mass%.

### Inorganic Filler (D)

As the inorganic filler (D), an inorganic filler usually used in the adhesive composition can be used without particular limitation.

Examples of the inorganic filler (D) include each inorganic powder made of ceramics, such as silica, clay, gypsum, calcium carbonate, barium sulfate, alumina (aluminum oxide), beryllium oxide, magnesium oxide, silicon carbide, silicon nitride, aluminum nitride, boron nitride; a metal or alloys, such as aluminum, copper, silver, gold, nickel, chromium, lead, tin, zinc, palladium, solder; and carbons, such as carbon nanotube, graphene.

The average particle diameter (d50) of the inorganic filler (D) is not particularly limited, but is preferably 0.01 to 6.0 µm, preferably 0.01 to 5.0 µm, more preferably 0.1 to 3.5 µm, and further preferably 0.6 to 1.0 µm from the viewpoint of enhancing the die attachability while suppressing the formation of any jig mark. The average particle diameter (d50) is a so-called median diameter, and refers to a particle diameter at which the cumulative volume is 50% when the particle size distribution is measured by the laser diffraction scattering method and the total volume of the particles is defined as 100% in the cumulative distribution. In one aspect of the adhesive composition of the present invention, an inorganic filler having an average particle diameter (d50) of 0.1 to 3.5 µm is included when attention is paid to the inorganic filler (D). In another preferable embodiment, it is possible to include an inorganic filler having an average particle diameter (d50) of more than 3.5 µm.

The Mohs hardness of the inorganic filler is not particularly limited, and is preferably 2 or more, more preferably 2 to 9, and further preferably 8 to 9 from the viewpoint of enhancing the die attachability while suppressing the occurrence of any jig mark. The Mohs hardness can be measured with a Mohs hardness meter.

The inorganic filler (D) can also be an inorganic filler having thermal conductivity. Such an inorganic filler (D) imparts thermal conductivity to the adhesive layer. When attention is paid to the inorganic filler (D), the adhesive composition of the present invention may contain a thermally conductive inorganic filler (inorganic filler having a thermal conductivity of 12 W/m•K or more) in an embodiment, or may contain a thermally non-conductive inorganic filler (inorganic filler having a thermal conductivity of less than 12 W/m•K) in an embodiment.

The inorganic filler (D) having thermal conductivity is a particle made of a thermally conductive material or a particle whose surface is coated with the thermally conductive material. The thermal conductivity of the thermally conductive material is preferably 12 W/m•K or more, and more preferably 30 W/m•K or more.

When the thermal conductivity of the thermally conductive material is the preferable lower limit or more, the amount of the inorganic filler (D) blended in order to obtain a desired thermal conductivity can be reduced. This suppresses increase in the melt viscosity of the adhesive layer and enables to further improve the filling property of the film into the unevenness of the substrate at the time of compression bonding to the substrate. As a result, generation of voids can be more reliably suppressed.

In the present invention, the thermal conductivity of the thermally conductive material means the thermal conductivity at 25° C., and the literature value for each material can be used. In a case where there is no description in the literatures, for example, the value measured in accordance with JIS R 1611 can be used in the case of ceramics, or the value measured in accordance with JIS H 7801 can be used in the case of metals in substitution for the literature value.

Examples of the inorganic filler (D) having thermal conductivity include thermally conductive ceramics, and preferred examples thereof include alumina particles (thermal conductivity: 36 W/m•K), aluminum nitride particles (thermal conductivity: 150 to 290 W/m•K), boron nitride particles (thermal conductivity: 60 W/m•K), zinc oxide particles (thermal conductivity: 54 W/m•K), a silicon nitride filler (thermal conductivity: 27 W/m•K), silicon carbide particles (thermal conductivity: 200 W/m•K), and magnesium oxide particles (thermal conductivity: 59 W/m•K).

In particular, alumina particles having high thermal conductivity are preferable in terms of dispersibility and availability. Further, aluminum nitride particles and boron nitride particles are preferable from the viewpoint of having even higher thermal conductivity than that of alumina particles. In the present invention, alumina particles and aluminum nitride particles are preferable among these particles.

Further, the inorganic filler (D) include particles whose surfaces are coated with a metal having thermal conductivity. Preferred examples of such particles include silicone resin particles and acrylic resin particles whose surfaces are coated with metals such as silver (thermal conductivity: 429 W/m•K), nickel (thermal conductivity: 91 W/m•K), gold (thermal conductivity: 329 W/m•K), and the like.

In particular, silicone resin particles whose surfaces are coated with silver are preferable from the viewpoint of a stress relaxing property and high heat resistance.

The inorganic filler (D) may be subjected to surface treatment or surface modification. Examples of the surface modifier used for such surface treatment or surface modification include treatment with a silane coupling agent, phosphoric acid or a phosphoric acid compound, or a surfactant. Besides the items described in the present specification, the descriptions of a silane coupling agent, or phosphoric acid or a phosphoric acid compound, and a surfactant in the section of a thermally conductive filler in WO 2018/203527 or the section of an aluminum nitride filler in WO 2017/158994 can be applied, for example.

A method of blending the inorganic filler (D) to resin components such as the epoxy resin (A), the epoxy resin curing agent (B), and the phenoxy resin (C) includes a method in which a powder inorganic filler and, if necessary, the surface modifier such as a silane coupling agent, phosphoric acid or a phosphoric acid compound, and a surfactant are directly blended (integral blending method), and a method in which a slurry inorganic filler obtained by dispersing an inorganic filler treated with a surface treatment agent such as a silane coupling agent, phosphoric acid or a phosphoric acid compound, and a surfactant in an organic solvent is blended.

A method of treating the inorganic filler (D) with a silane coupling agent is not particularly limited. Examples thereof include a wet method of mixing the inorganic filler (D) and a silane coupling agent in a solvent, a dry method of mixing the inorganic filler (D) and a silane coupling agent in a gas phase, and the above integral blending method.

In particular, the aluminum nitride particles contribute to high thermal conductivity, but tend to generate ammonium ions due to hydrolysis. It is therefore preferable that the aluminum nitride particles are used in combination with a phenol resin having a low moisture absorption rate and hydrolysis is suppressed by surface modification. As a surface modification method of the aluminum nitride, a method of providing a surface layer with an oxide layer of aluminum oxide to improve water proofness and then preforming surface treatment with phosphoric acid or a phosphoric acid compound to improve affinity with the resin is particularly preferable.

The silane coupling agent is a compound in which at least one hydrolyzable group such as an alkoxy group and an aryloxy group is bonded to a silicon atom. In addition to these groups, an alkyl group, an alkenyl group, or an aryl group may be bonded to the silicon atom. The alkyl group is preferably an alkyl group substituted with an amino group, an alkoxy group, an epoxy group, or a (meth)acryloyloxy group, and more preferably an alkyl group substituted with an amino group (preferably, a phenylamino group), an alkoxy group (preferably, a glycidyloxy group), or a (meth)acryloyloxy group.

Examples of the silane coupling agent include 2-(3,4-epoxycyclohexyl) ethyltrimethoxysilane, 3-glycidyloxypropyltrimethoxysilane, 3-glycidyloxypropyltriethoxysilane, 3-glycidyloxypropylmethyldimethoxysilane, 3-glycidyloxypropylmethyldiethoxysilane, dimethyldimethoxysilane, dimethyldiethoxysilane, methyltrimethoxysilane, methyltriethoxysilane, phenyltrimethoxysilane, phenyltriethoxysilane, N-phenyl-3-aminopropyltrimethoxysilane, 3-methacryloyloxypropylmethyldimethoxysilane, 3-methacryloyloxypropyltrimethoxysilane, 3-methacryloyloxypropylmethyldiethoxysilane, 3-methacryloyloxypropyltriethoxysilane, and the like.

The surface modifier is contained in an amount of preferably 0.1 to 25.0 parts by mass, more preferably 0.1 to 10 parts by mass, and further preferably 0.1 to 2.0 parts by mass based on 100 parts by mass of the inorganic filler (D).

By adjusting the content of the surface modifier to the preferable range, it is possible to suppress peeling at the adhesion interface due to volatilization of an excessive silane coupling agent and surfactant in the heating process in semiconductor assembling (for example, a reflow process) while aggregation of the inorganic filler (D) is suppressed. As a result, generation of voids can be suppressed and die attachability can be improved.

Examples of the shape of the inorganic filler (D) include a flake shape, a needle shape, a filament shape, a spherical shape, and a scaly shape, and a spherical shape is preferable from the viewpoint of high filling and fluidity.

In the adhesive composition of the present invention, the proportion of the inorganic filler (D) in the total content of the epoxy resin (A), the epoxy resin curing agent (B), the phenoxy resin (C), and the inorganic filler (D) is preferably 5 to 70 vol%. When the content proportion of the inorganic filler (D) is equal to or more than the above lower limit, it is possible to improve the die attachability while suppressing the occurrence of jig marks when a film-like adhesive is formed. Further, a desired melt viscosity may be imparted. Also, the content proportion of the inorganic filler (D) being the upper limit or less can impart a desired melt viscosity to the film-like adhesive, and thus can suppress generation of voids. Further, such a content proportion allows relaxing of internal stress generated in the semiconductor package during thermal change, and also allows improvement of an adhesive force.

The proportion of the inorganic filler (D) in the total content of the epoxy resin (A), the epoxy resin curing agent (B), the phenoxy resin (C), and the inorganic filler (D) is preferably 20 to 70 vol%, more preferably 20 to 60 vol%, and further preferably 20 to 50 vol%. The proportion may be 30 to 70 vol%, 30 to 50 vol%, or 35 to 50 vol%.

The content (vol%) of the inorganic filler (D) can be calculated from the contained mass and specific gravity of each of the epoxy resin (A), the epoxy resin curing agent (B), the phenoxy resin (C), or the inorganic filler (D).

In a preferred embodiment of the adhesive composition of the present invention, the average particle diameter (d50) of the inorganic filler (D) is 0.01 to 5.0 µm, and the proportion of the inorganic filler (D) in a total content of the epoxy resin (A), the epoxy resin curing agent (B), the phenoxy resin (C), and the inorganic filler (D) is 5 to 70 vol%.

### Other Components

The adhesive composition of the present invention may contain a polymer compound in addition to the epoxy resin (A), the epoxy resin curing agent (B), the phenoxy resin (C), and the inorganic filler (D) as long as the effects of the present invention are not impaired.

Examples of the polymer compound include natural rubber, butyl rubber, isoprene rubber, chloroprene rubber, silicone rubber, an ethylene-vinyl acetate copolymer, an ethylene-(meth)acrylic acid copolymer, an ethylene-(meth)acrylic acid ester copolymer, polybutadiene resin, polycarbonate resin, thermoplastic polyimide resin, polyamide resins such as 6-nylon and 6,6-nylon, (meth)acrylic resin, polyester resins such as polyethylene terephthalate and polybutylene terephthalate, polyamideimide resin, and fluororesin. These polymer compounds may be used singly, or in combination of two or more kinds thereof.

The adhesive composition of the present invention may further contain, for example, an organic solvent (e.g., methyl ethyl ketone), an ion trapping agent (ion capturing agent), a curing catalyst, a viscosity adjusting agent, an antioxidant, a flame retardant, and/or a coloring agent. For example, other additives described in WO 2017/158994 may be included.

The proportion of the total content of the epoxy resin (A), the epoxy resin curing agent (B), the phenoxy resin (C), and the inorganic filler (D) in the adhesive composition of the present invention can be, for example, 60 mass% or more, preferably 70 mass% or more, further preferably 80 mass% or more, and may also be 90 mass% or more. Also, the proportion may be 100 mass%, and can be 95 mass% or less.

The adhesive composition of the present invention can be suitably used for obtaining the film-like adhesive of the present invention. However, the adhesive composition of the present invention is not limited to the film-like adhesive, and can also be suitably used for obtaining a liquid adhesive.

The adhesive composition of the present invention can be obtained by mixing the above components at a temperature at which the epoxy resin (A) is practically not cured. The order of mixing is not particularly limited. Resin components such as the epoxy resin (A) and the phenoxy resin (C) may be mixed together with a solvent, if necessary, and the inorganic filler (D) and the epoxy resin curing agent (B) may then be mixed. In this case, the mixing in the presence of the epoxy resin curing agent (B) may be performed at a temperature at which the epoxy resin (A) is practically not cured, and the mixing of the resin components in the absence of the epoxy resin curing agent (B) may be performed at a higher temperature.

From the viewpoint of suppressing thermal curing of the epoxy resin (A), the adhesive composition of the present invention is preferably stored under a temperature condition at 10° C. or lower before use (before being formed into a film-like adhesive).

### Film-Like Adhesive

The film-like adhesive of the present invention is a film-like adhesive obtained from the adhesive composition of the present invention, and contains the epoxy resin (A), the epoxy resin curing agent (B), the phenoxy resin (C), and the inorganic filler (D). Among the additives described as other additives in the adhesive composition of the present invention, the additives other than the organic solvent in addition to the above components may be contained. The organic solvent is usually removed from the adhesive composition by drying, but may be contained as long as it is about 0.1 to 1000 ppm.

Here, the “film” means a thin film having a thickness of 200 µm or less. The shape and size, etc., of the film is not particularly limited, and can be adjusted, if appropriate, in accordance with the use form.

The film-like adhesive of the present invention has the nanoindentation hardness and the Young’s modulus described above before curing.

The film-like adhesive of the present invention suppresses formation of a jig mark, and is excellent in die attachability. The reason is not clear, but it is considered that the reason is that the adhesive composition containing the epoxy resin (A), the epoxy resin curing agent (B), the phenoxy resin (C), and the inorganic filler (D) is prepared, and the elastic modulus and content of the phenoxy resin are made specific, and the nanoindentation hardness and Young’s modulus of the film-like adhesive at 25° C. before curing are made specific, whereby sufficient film surface hardness is maintained at the time of pickup, and the jig mark is less likely to remain, and low melt viscosity is obtained at the time of mounting, so that air caught in the interface with the adherend can be discharged while absorbing the jig mark and unevenness of the adherend to some extent.

In the film-like adhesive of the present invention, when the film-like adhesive before thermal curing is heated from 25° C. at a temperature elevation rate of 5° C./min, the melt viscosity at 120° C. is preferably in the range of 100 to 10,000 Pa•s, more preferably in the range of 200 to 10,000 Pa•s, more preferably in the range of 500 to 10,000 Pa•s, more preferably in the range of 1,000 to 10,000 Pa•s, more preferably in the range of 1,500 to 10,000 Pa•s, more preferably in the range of 8,000 to 10,000 Pa•s, and further preferably in the range of 8,000 to 9,200 Pa•s from the viewpoint of enhancing the die attachability. By adjusting the melt viscosity at 120° C. to a level within the preferable range, generation of voids between unevennesses in the wiring board can be effectively reduced when the semiconductor chip provided with the film-like adhesive is thermocompression bonded on the wiring board.

The melt viscosity can be determined by the method described in Examples described later.

The melt viscosity can be controlled by the content of the inorganic filler (D), the kind of the inorganic filler (D), the kinds of coexisting compounds or resins such as the epoxy resin (A), epoxy resin curing agent (B), and the phenoxy resin (C), and the contents thereof.

The film-like adhesive of the present invention preferably has a thickness of 1 to 60 µm.The thickness is more preferably 3 to 30 µm, and particularly preferably 5 to 20 µm. The thickness of the film-like adhesive is preferably 5 to 15 µm from the viewpoint that the effect of the present invention can be further exhibited, that is, excellent die attachability and suppressing the occurrence of the jig mark and void during pickup can be exhibited even when the film-like adhesive is used as a thin film.

The thickness of the film-like adhesive can be measured by a contact type linear gauge method (desk-top contact type thickness measurement apparatus).

For example, the film-like adhesive of the present invention can be formed by preparing the adhesive composition (varnish) of the present invention, applying the composition onto a release-treated substrate film, and drying the composition as necessary. The adhesive composition usually contains an organic solvent.

As the release-treated substrate film, any release-treated substrate film that functions as a cover film of the obtained film-like adhesive can be used, and a publicly known film can be appropriately employed. Examples thereof include release-treated polypropylene (PP), release-treated polyethylene (PE), release-treated polyethylene terephthalate (PET).

A publicly known method can be employed, if appropriate, as the application method, and examples thereof include a method using, for instance, a roll knife coater, a gravure coater, a die coater, or a reverse coater.

The drying may be performed as long as the organic solvent is removed from the adhesive composition without curing the epoxy resin (A) to obtain a film-like adhesive. The drying temperature can be set, if appropriate, depending on the kinds of the epoxy resin (A), the phenoxy resin (C), and the epoxy resin curing agent (B) to be used. For example, the drying may be performed while holding at a temperature of, for example, 80 to 150° C. for 1 to 20 min.

The film-like adhesive of the present invention may be formed of the film-like adhesive of the present invention alone, or may have a form obtained by bonding a release-treated substrate film described above to at least one surface of the film-like adhesive. The film-like adhesive of the present invention may be a form obtained by cutting the film into an appropriate size, or a form obtained by winding the film into a roll form.

In the film-like adhesive of the present invention, the arithmetic average roughness Ra of at least one surface thereof (that is, at least one surface to be bonded to an adherend) is preferably 3.0 µm or less, and the arithmetic average roughness Ra of surfaces on both sides to be bonded to the adherend is more preferably 3.0 µm or less.

The arithmetic average roughness Ra is more preferably 2.0 µm or less, and further preferably 1.5 µm or less. The lower limit is not particularly limited, but is practically 0.1 µm or more.

From the viewpoint of suppressing curing of the epoxy resin (A), the film-like adhesive of the present invention is preferably stored under a temperature condition at 10° C. or lower before use (before curing).

### Semiconductor Package and Producing Method Thereof

In the semiconductor package of the present invention, at least one of between a semiconductor chip and a wiring board and between semiconductor chips is bonded by a thermally curable component of the film-like adhesive of the present invention. Ordinarily used semiconductor chips and wiring boards may be used. The bonding conditions will be described later in the description of the producing method.

The method of producing a semiconductor package of the present invention can be produced by a normal method of producing a semiconductor package except that the film-like adhesive of the present invention is used for bonding at least one of between a semiconductor chip and a wiring board and between semiconductor chips.

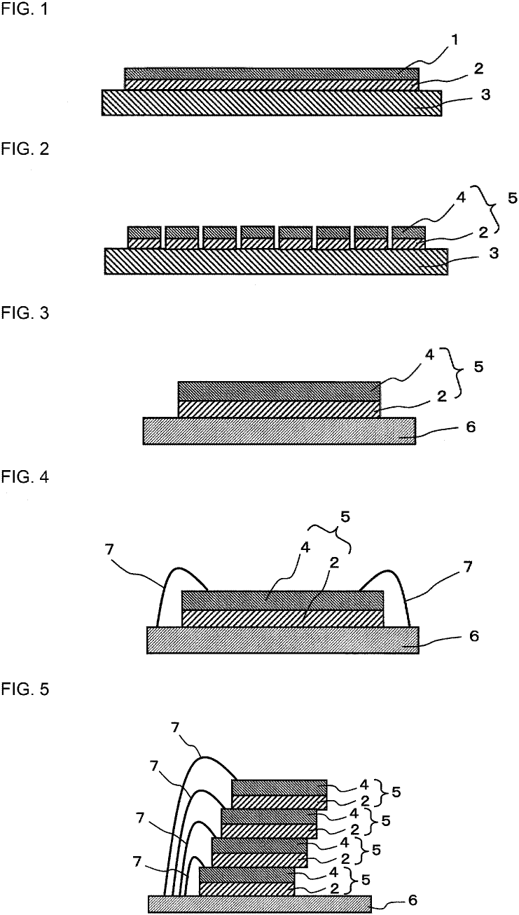

Hereinafter, preferred embodiments of a semiconductor package and a method of producing the same of the present invention will be described in detail with reference to the drawings. Note that, in the descriptions and drawings below, the same reference numerals are given to the same or corresponding components, and overlapping descriptions will be omitted. FIGS. 1 to 7 are schematic longitudinal cross-sectional views each illustrating a preferred embodiment of each step of a method of producing a semiconductor package of the present invention. FIGS. 1 to 7 are schematic diagrams, and for convenience of description, the sizes, relative magnitude relationships, etc., of members such as semiconductor wafers may be different from actual ones.

In a preferable embodiment of the method of producing a semiconductor package of the present invention, as a first step, as illustrated in FIG. 1, the film-like adhesive of the present invention is thermocompression bonded to the back surface of a semiconductor wafer 1 in which at least one semiconductor circuit is formed on a surface (that is, a surface of the semiconductor wafer 1 on which the semiconductor circuit is not formed) to provide an adhesive layer 2, and a dicing tape 3 is provided with this adhesive interposed therebetween. At this time, a product in which the adhesive layer 2 and the dicing tape 3 are integrated may be thermocompression bonded to the back surface of the semiconductor wafer 1 at a time. For the condition of thermocompression bonding, thermocompression bonding is performed at a temperature at which the epoxy resin (A) is not thermally cured actually. For example, the condition of a temperature of 70° C. and a pressure of 0.3 MPa is exemplified.

As the semiconductor wafer 1, a semiconductor wafer where at least one semiconductor circuit is formed on the surface can be appropriately used. Examples thereof include a silicon wafer, a SiC wafer, a GaAs wafer, and a GaN wafer.

As the adhesive layer 2, one layer of the film-like adhesive of the present invention may be used alone, or two or more layers thereof may be layered and used. As a method of providing such an adhesive layer 2 on the back surface of the wafer 1, a method capable of laminating the film-like adhesive on the back surface of the semiconductor wafer 1 can be appropriately employed. Examples thereof include a method of bonding the film-like adhesive to the back surface of the semiconductor wafer 1 and then, in a case of laminating two or more layers, sequentially laminating the film-like adhesives to a desired thickness, a method of laminating the film-like adhesives to a desired thickness in advance and then bonding this to the back surface of the semiconductor wafer 1, and the like. An apparatus used when such an adhesive layer 2 is provided on the back surface of the semiconductor wafer 1 is not particularly limited. For example, a publicly known apparatus such as a roll laminator and a manual laminator can be used, if appropriate.

The dicing tape 3 is not particularly limited, and a publicly known dicing tape can be used, if appropriate.

Next, as a second step, the semiconductor wafer 1 and the adhesive layer 2 are simultaneously diced as illustrated in FIG. 2. Thus, a semiconductor chip 5 with an adhesive layer, including the semiconductor wafer 1 (semiconductor chip 4) and the adhesive layer 2 on the dicing tape 3, is obtained. Further, an apparatus used for dicing is not particularly limited, and a publicly known dicing apparatus can be used, if appropriate.

Then, as a third step, as illustrated in FIG. 3, the dicing tape 3 is removed from the adhesive layer 2, and the semiconductor chip 5 with an adhesive layer and the wiring board 6 are thermocompression bonded with the adhesive layer 2 interposed therebetween. In this way, the semiconductor chip 5 with an adhesive layer is mounted on the wiring board 6. As the wiring board 6, a substrate where a semiconductor circuit is formed on the surface can be appropriately used. Examples thereof include a print circuit board (PCB), various lead frames, and a substrate where electronic components such as a resistive element and a capacitor are mounted on the surface of a substrate.

As a method of removing (peeling) the dicing tape 3 from the adhesive layer (a method of picking up a semiconductor chip with an adhesive layer), a pickup method using an ordinary jig can be adopted. Specific examples include a method of peeling off the dicing tape 3 while using a jig such as a needle or a slider. According to the producing method of the present invention, in this step, the jig mark is less likely to occur on the surface of the film-like adhesive.

A method of mounting the semiconductor chip 5 with an adhesive layer on the wiring board 6 is not particularly limited. A conventional method that enables to bond the semiconductor chip 5 with an adhesive layer to the wiring board 6 or the electronic component mounted on the surface of the wiring board 6 by utilizing the adhesive layer 2 can be appropriately employed. Examples of such a mounting method include a publicly known heating and pressurizing method such as a method using a mounting technique using a flip chip bonder having a heating function from the upper part, a method using a die bonder having a heating function from only the lower part, and a method using a laminator. For the condition of mounting (thermocompression bonding), mounting is performed at a temperature at which the epoxy resin (A) is not thermally cured actually. Examples include the condition at a temperature of 120° C. and a pressure of 0.1 MPa for 1.0 second.

As such, mounting the semiconductor chip 5 with an adhesive layer on the wiring board 6 with the adhesive layer 2 formed from the film-like adhesive of the present invention interposed therebetween allows the film-like adhesive to conform to the unevenness on the wiring board 5, formed due to the electronic component, and thereby enables to firmly adhere and fix the semiconductor chip 4 and the wiring board 6.

According to the producing method of the present invention, in this step, the void is less likely to occur at the interface between the adhesive layer formed of the film-like adhesive and the wiring board, and mounting can be performed with high reliability.

Next, as a fourth step, the adhesive layer 2 (film-like adhesive of the present invention) is thermally cured to produce a thermally curable component. The temperature for thermal curing is not particularly limited as long as it is a temperature equal to or more than the thermal curing start temperature of the film-like adhesive of the present invention. The temperature varies depending on the kinds of the epoxy resin (A), the phenoxy resin (C), and the epoxy resin curing agent (B) to be used. The temperature is, although it cannot be said unconditionally, for example, preferably 100 to 180° C., and more preferably 140 to 180° C. from the viewpoint that curing at a higher temperature allows curing in a short time. When the temperature is less than the thermal curing start temperature, thermal curing does not sufficiently proceed, and as a result, the strength of the adhesion layer 2 tends to decrease. On the other hand, when the temperature is more than the above upper limit, the epoxy resin, the curing agent, the additives, and the like in the film-like adhesive volatilize during the curing process and thus tend to foam. Also, the time for curing treatment is preferably, for example, 10 to 120 minutes.

Next, in the method of producing a semiconductor package of the present invention, it is preferable that the wiring board 6 and the semiconductor chip 5 with an adhesive layer are connected via a bonding wire 7 as illustrated in FIG. 4. Such a connection method is not particularly limited, and a publicly known method, for example, a wire bonding method or a TAB (Tape Automated Bonding) method can be employed, if appropriate.

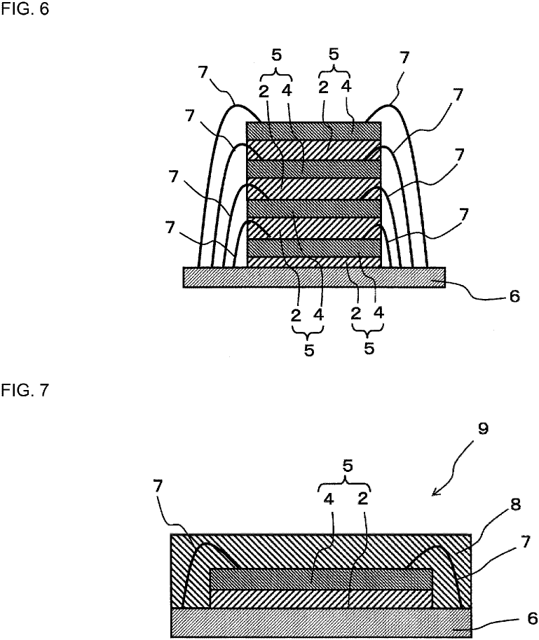

Further, a plurality of semiconductor chips 4 can be stacked by thermocompression bonding another semiconductor chip 4 to a surface of the mounted semiconductor chip 4, performing thermal curing, and then connecting the semiconductor chips 4 again to the wiring board 6 by wire bonding. Examples of the stacking method include a method of stacking the semiconductor chips in slightly different positions as illustrated in FIG. 5, and a method of stacking the semiconductor chips by increasing the thicknesses of the adhesive layers 2 of the second layer or later and thereby embedding the bonding wire 7 in each adhesive layer 2 as illustrated in FIG. 6.

In the method of producing a semiconductor package of the present invention, it is preferable to seal the wiring board 6 and the semiconductor chip 5 with an adhesive layer by using a sealing resin 8 as illustrated in FIG. 7. In this way, a semiconductor package 9 can be obtained. The sealing resin 8 is not particularly limited, and a publicly known sealing resin that can be used for the production of the semiconductor package can be appropriately used. In addition, a sealing method using the sealing resin 8 is not particularly limited, and a publicly known method can be employed, if appropriate.

According to the method of producing the semiconductor package of the present invention, even in the form of a thin film, it is possible to suppress formation of a jig mark in a pickup step and to suppress formation of voids in a die attach step.

### EXAMPLES

Hereinafter, the present invention will be described in more detail based on Examples and Comparative Examples. However, the present invention is not limited to the following Examples. Also, the room temperature means 25° C., MEK is methyl ethyl ketone, and PET is polyethylene terephthalate.

### Example 1

In a 1,000 ml separable flask, 56 parts by mass of triphenylmethane type epoxy resin (trade name: EPPN-501H, mass average molecular weight: 1,000, softening point: 55° C., semi-solid, epoxy equivalent amount: 167 g/eq, manufactured by Nippon Kayaku Co., Ltd.), 49 parts by mass of bisphenol A type epoxy resin (trade name: YD-128, mass average molecular weight: 400, softening point: 25° C. or less, liquid, epoxy equivalent amount: 190 g/eq, manufactured by NSCC Epoxy Manufacturing Co., Ltd.), 30 parts by mass of bisphenol A type phenoxy resin (trade name: YP-50, mass average molecular weight: 70,000, Tg: 84° C., normal temperature (25° C.) elastic modulus: 1,700 MPa, manufactured by NSCC Epoxy Manufacturing Co., Ltd.), and 67 parts by mass of MEK were heated with stirring at 110° C. for 2 hours to prepare a resin varnish.

Subsequently, this resin varnish was transferred to an 800 ml planetary mixer, and 55 parts by mass of alumina filler (trade name: AO-502, manufactured by Admatechs, average particle diameter (d50): 0.6 µm, Mohs hardness: 9 Mohs, thermal conductivity: 36 W/m•K) was introduced to the mixer. Further, 8.5 parts by mass of imidazole type curing agent (trade name: 2PHZ-PW, manufactured by Shikoku Chemicals Corporation) and 3.0 parts by mass of silane coupling agent (trade name: Sila-Ace S-510, manufactured by JNC Corporation) were introduced to the mixer, and the contents were then mixed with stirring for 1 hour at room temperature. Then defoaming under vacuum was conducted, thus obtaining a mixed varnish.

Thereafter, the obtained mixed varnish was applied onto a release-treated PET film (release film) having a thickness of 38 µm and then dried by heating at 130° C. for 10 minutes to obtain a film-like adhesive with a release film, having a length of 300 mm, a width of 200 mm, and a thickness of 10 µm. The obtained film-like adhesive was stored at 10° C. or lower. The epoxy resin was not cured after the drying.

### Example 2

A film-like adhesive with a release film was prepared in the same manner as in Example 1 except that the amount of the alumina filler (trade name: AO-502, manufactured by Admatechs, average particle diameter (d50): 0.6 µm, Mohs hardness: 9 Mohs, thermal conductivity: 36 W/m•K) used was 320 parts by mass.

### Example 3

A film-like adhesive with a release film was prepared in the same manner as in Example 1 except that the amount of the alumina filler (trade name: AO-502, manufactured by Admatechs, average particle diameter (d50): 0.6 µm, Mohs hardness: 9 Mohs, thermal conductivity: 36 W/m•K) used was 480 parts by mass.

### Example 4

A film-like adhesive with a release film was prepared in the same manner as in Example 2 except that the phenoxy resin was replaced to a bisphenol A/F copolymerized phenoxy resin (trade name: YP-70, mass average molecular weight: 55,000, Tg: 72° C., normal temperature elastic modulus: 1400 MPa, manufactured by NSCC Epoxy Manufacturing Co., Ltd.).

### Example 5

A film-like adhesive with a release film was prepared in the same manner as in Example 2 except that the phenoxy resin was replaced with a low elasticity high heat resistance phenoxy resin (trade name: FX-310, mass average molecular weight: 40,000, Tg: 110° C., normal temperature elastic modulus: 500 MPa, manufactured by NSCC Epoxy Manufacturing Co., Ltd.).

### Example 6

A film-like adhesive with a release film was prepared in the same manner as in Example 1 except that the use amount of the bisphenol A type phenoxy resin (trade name: YP-50, mass average molecular weight: 70,000, Tg: 84° C., normal temperature elastic modulus: 1700 MPa, manufactured by NSCC Epoxy Manufacturing Co., Ltd.) was 44 parts by mass, and the use amount of the alumina filler (trade name: AO-502, manufactured by Admatechs, average particle diameter (d50): 0.6 µm, Mohs hardness: 9 Mohs, thermal conductivity: 36 W/m•K) was 350 parts by mass.

### Example 7

A film-like adhesive with a release film was prepared in the same manner as in Example 1 except that the use amount of the bisphenol A type phenoxy resin (trade name: YP-50, mass average molecular weight: 70,000, Tg: 84° C., normal temperature elastic modulus: 1700 MPa, manufactured by NSCC Epoxy Manufacturing Co., Ltd.) was 70 parts by mass, and the use amount of the alumina filler (trade name: AO-502, manufactured by Admatechs, average particle diameter (d50): 0.6 µm, Mohs hardness: 9 Mohs, thermal conductivity: 36 W/m•K) was 400 parts by mass.

### Example 8

A film-like adhesive with a release film was prepared in the same manner as in Example 1 except that the use amount of the bisphenol A type phenoxy resin (trade name: YP-50, mass average molecular weight: 70,000, Tg: 84° C., normal temperature elastic modulus: 1700 MPa, manufactured by NSCC Epoxy Manufacturing Co., Ltd.) was replaced to 50 parts by mass and the inorganic filler was replaced to 360 parts by mass of a silver filler (trade name: AG-4-8F, manufactured by DOWA Electronics Materials Co., Ltd., average particle diameter (d50): 2.0 µm, Mohs hardness: 2 Mohs, thermal conductivity: 429 W/m•K).

### Example 9

A film-like adhesive with a release film was prepared in the same manner as in Example 1 except that the use amount of the bisphenol A type phenoxy resin (trade name: YP-50, mass average molecular weight: 70,000, Tg: 84° C., normal temperature elastic modulus: 1700 MPa, manufactured by NSCC Epoxy Manufacturing Co., Ltd.) was replaced to 50 parts by mass and the inorganic filler was replaced to 610 parts by mass of a silver filler (trade name: AG-4-8F, manufactured by DOWA Electronics Materials Co., Ltd., average particle diameter (d50): 2.0 µm, Mohs hardness: 2 Mohs, thermal conductivity: 429 W/m•K).

### Example 10

A film-like adhesive with a release film was prepared in the same manner as in Example 1 except that the use amount of the bisphenol A type phenoxy resin (trade name: YP-50, mass average molecular weight: 70,000, Tg: 84° C., normal temperature elastic modulus: 1700 MPa, manufactured by NSCC Epoxy Manufacturing Co., Ltd.) was replaced to 50 parts by mass and the inorganic filler was replaced to 950 parts by mass of a silver filler (trade name: AG-4-8F, manufactured by DOWA Electronics Materials Co., Ltd., average particle diameter (d50): 2.0 µm, Mohs hardness: 2 Mohs, thermal conductivity: 429 W/m•K).

### Example 11

A film-like adhesive with a release film was prepared in the same manner as in Example 1 except that the inorganic filler was replaced to 14 parts by mass of a silica filler (trade name: SO-25R, manufactured by, average particle diameter (d50): 0.5 µm, Mohs hardness: 7 Mohs, thermal conductivity: 1 W/m•K).

### Example 12

A film-like adhesive with a release film was prepared in the same manner as in Example 1 except that the inorganic filler was replaced to 67 parts by mass of a silica filler (trade name: SO-25R, manufactured by, average particle diameter (d50): 0.5 µm, Mohs hardness: 7 Mohs, thermal conductivity: 1 W/m•K).

### Example 13

A film-like adhesive with a release film was prepared in the same manner as in Example 1 except that the inorganic filler was replaced to 14 parts by mass of a nano-silica filler (trade name: RY-200, manufactured by NIPPON AEROSIL CO., LTD., average particle diameter (d50): 12 nm, Mohs hardness: 7 Mohs, thermal conductivity: 1 W/m•K).

### Example 14

A film-like adhesive with a release film was prepared in the same manner as in Example 1 except that the inorganic filler was replaced to 67 parts by mass of a nano-silica filler (trade name: RY-200, manufactured by NIPPON AEROSIL CO., LTD., average particle diameter (d50): 12 nm, Mohs hardness: 7 Mohs, thermal conductivity: 1 W/m•K).

### Example 15

A film-like adhesive was prepared in the same manner as in Example 1 except that the use amount of the bisphenol A type phenoxy resin (trade name: YP-50, mass average molecular weight: 70,000, Tg: 84° C., normal temperature elastic modulus: 1700 MPa, manufactured by NSCC Epoxy Manufacturing Co., Ltd.) was 15 parts by mass.

### Example 16

A film-like adhesive was prepared in the same manner as in Example 1 except that the use amount of the bisphenol A type phenoxy resin (trade name: YP-50, mass average molecular weight: 70,000, Tg: 84° C., normal temperature elastic modulus: 1700 MPa, manufactured by NSCC Epoxy Manufacturing Co., Ltd.) was 130 parts by mass.

### Example 17

A film-like adhesive was prepared in the same manner as in Example 1 except that the inorganic filler was replaced to 30 parts by mass of a silica filler (trade name: FB-7SDS, Denka Company Limited, average particle diameter (d50): 5.4 µm, Mohs hardness: 7 Mohs, thermal conductivity: 1 W/m•K) whose particle size distribution was adjusted using a 10.0 µm mesh filter.

### Comparative Example 1

A film-like adhesive with a release film was prepared in the same manner as in Example 1 except that the use amount of the bisphenol A type phenoxy resin (trade name: YP-50, mass average molecular weight: 70,000, Tg: 84° C., normal temperature elastic modulus: 1700 MPa, manufactured by NSCC Epoxy Manufacturing Co., Ltd.) was 10 parts by mass, and the use amount of the alumina filler (trade name: AO-502, manufactured by Admatechs, average particle diameter (d50): 0.6 µm, Mohs hardness: 9 Mohs, thermal conductivity: 36 W/m•K) was 275 parts by mass.

### Comparative Example 2

A film-like adhesive with a release film was prepared in the same manner as in Example 1 except that the use amount of the bisphenol A type phenoxy resin (trade name: YP-50, mass average molecular weight: 70,000, Tg: 84° C., normal temperature elastic modulus: 1700 MPa, manufactured by NSCC Epoxy Manufacturing Co., Ltd.) was 190 parts by mass, and the use amount of the alumina filler (trade name: AO-502, manufactured by Admatechs, average particle diameter (d50): 0.6 µm, Mohs hardness: 9 Mohs, thermal conductivity: 36 W/m•K) was 670 parts by mass.

### Comparative Example 3

A film-like adhesive with a release film was prepared in the same manner as in Example 1 excepnott that the phenoxy resin was replaced to 10 parts by mass of bisphenol F + 1,6-hexanediol diglycidyl ether type phenoxy resin (trade name: YX-7180, mass average molecular weight: 50,000, Tg: 15° C., normal temperature elastic modulus: 200 MPa, manufactured by Mitsubishi Chemical Corporation), and the use amount of the alumina filler (trade name: AO-502, manufactured by Admatechs, average particle diameter (d50): 0.6 µm, Mohs hardness: 9 Mohs, thermal conductivity: 36 W/m•K) was 275 parts by mass.

### Comparative Example 4

A film-like adhesive with a release film was prepared in the same manner as in Example 1 except that the phenoxy resin was replaced to 190 parts by mass of bisphenol F + 1,6-hexanediol diglycidyl ether type phenoxy resin (trade name: YX-7180, mass average molecular weight: 50,000, Tg: 15° C., normal temperature elastic modulus: 200 MPa, manufactured by Mitsubishi Chemical Corporation), and the use amount of the alumina filler (trade name: AO-502, manufactured by Admatechs, average particle diameter (d50): 0.6 µm, Mohs hardness: 9 Mohs, thermal conductivity: 36 W/m•K) was 670 parts by mass.

### Comparative Example 5

A film-like adhesive was prepared in the same manner as in Example 1 except that the phenoxy resin was replaced to 30 parts by mass of a bisphenol F + 1,6-hexanediol diglycidyl ether type phenoxy resin (trade name: YX-7180, mass average molecular weight: 50,000, Tg: 15° C., normal temperature elastic modulus: 200 MPa, manufactured by Mitsubishi Chemical Corporation).

### Comparative Example 6

A film-like adhesive with a release film was prepared in the same manner as in Example 1 except that the phenoxy resin was replaced with 40 parts by mass of an acrylic polymer solution (trade name: S-2060, solid content 25% (organic solvent: toluene), manufactured by Toagosei Co., Ltd.) (including 10 parts by mass of the acrylic polymer), and the use amount of the alumina filler (trade name: AO-502, manufactured by Admatechs, average particle diameter (d50): 0.6 µm, Mohs hardness: 9 Mohs, thermal conductivity: 36 W/m•K) was 275 parts by mass.

### Comparative Example 7

A film-like adhesive with a release film was prepared in the same manner as in Example 1 except that the phenoxy resin was replaced with 760 parts by mass of an acrylic polymer solution (trade name: S-2060, solid content 25% (organic solvent: toluene), manufactured by Toagosei Co., Ltd.) (including 190 parts by mass of the acrylic polymer), and the use amount of the alumina filler (trade name: AO-502, manufactured by Admatechs, average particle diameter (d50): 0.6 µm, Mohs hardness: 9 Mohs, thermal conductivity: 36 W/m•K) was 670 parts by mass.

### Comparative Example 8

A film-like adhesive was prepared in the same manner as in Example 1 except that the phenoxy resin was replaced with 1600 parts by mass of an acrylic polymer solution (trade name: S-2060, solid content 25% (organic solvent: toluene), manufactured by Toagosei Co., Ltd.) (including 400 parts by mass of the acrylic polymer).

### Comparative Example 9

A film-like adhesive was prepared in the same manner as in Example 1 except that the phenoxy resin was replaced with 120 parts by mass of an acrylic polymer solution (trade name: S-2060, solid content 25% (organic solvent: toluene), manufactured by Toagosei Co., Ltd.) (including 30 parts by mass of the acrylic polymer).

### Comparative Example 10

A film-like adhesive with a release film was prepared in the same manner as in Example 1 except that the epoxy resin was 50 parts by mass of a triphenylmethane epoxy resin (trade name: EPPN-501H, mass average molecular weight: 1,000, softening point: 55° C., semi-solid, epoxy equivalent: 167 g/eq, manufactured by Nippon Kayaku Co., Ltd.), the use amount of the bisphenol A phenoxy resin (trade name: YP-50, mass average molecular weight: 70,000, Tg: 84° C., normal temperature elastic modulus: 1700 MPa, manufactured by NSCC Epoxy Manufacturing Co., Ltd.) was 100 parts by mass, the use amount of the alumina filler (trade name: AO-502, manufactured by Admatechs, average particle diameter (d50): 0.6 µm, Mohs hardness: 9 Mohs, thermal conductivity: 36 W/m•K) was 450 parts by mass, and the use amount of the silane coupling agent (trade name: Sila-Ace S-510, manufactured by JNC Corporation) was 7.0 parts by mass.

### Comparative Example 11

A film-like adhesive with a release film was prepared in the same manner as in Example 1 except that the inorganic filler was replaced to 8 parts by mass of silicone filler (trade name: MSP-SN05, manufactured by Nikko Rica Corporation, average particle diameter (d50): 0.5 µm, Mohs hardness: 1 Mohs or less, thermal conductivity: 0.2 W/m•K).

### Comparative Example 12

A film-like adhesive with a release film was prepared in the same manner as in Example 1 except that the inorganic filler was replaced to 95 parts by mass of silicone filler (trade name: MSP-SN05, manufactured by Nikko Rica Corporation, average particle diameter (d50): 0.5 µm, Mohs hardness: 1 Mohs or less, thermal conductivity: 0.2 W/m•K).

### Comparative Example 13

A film-like adhesive with a release film was prepared in the same manner as in Example 1 except that the inorganic filler was replaced to 220 parts by mass of silicone filler (trade name: MSP-SN05, manufactured by Nikko Rica Corporation, average particle diameter (d50): 0.5 µm, Mohs hardness: 1 Mohs or less, thermal conductivity: 0.2 W/m•K).

### Comparative Example 14

A film-like adhesive was prepared in the same manner as in Example 1 except that the inorganic filler was not used.

The elastic moduli at 25° C. of the phenoxy resin and the acrylic resin used in each Example and Comparative Example were measured as follows.

### Normal Temperature (25° C.) Elastic Modulus

In a 500 ml separable flask, 30 parts by mass of each of various types of phenoxy resins and 70 parts by mass of MEK (methyl ethyl ketone) were heated with stirring at a temperature of 110° C. for 2 hours to obtain a resin varnish.

Thereafter, this resin varnish was applied onto a release-treated PET film (release film) having a thickness of 38 µm and then dried by heating at 130° C. for 10 minutes to obtain a phenoxy resin film having a length of 300 mm, a width of 200 mm, and a thickness of 100 µm.

This phenoxy resin film was cut into a size of 5 mm × 17 mm. The cut film is measured by using a dynamic viscoelasticity measurement apparatus (trade name: Rheogel-E4000F, manufactured by UBM) under the condition at a measurement temperature range of 0 to 100° C., a temperature elevation rate of 5° C./min, and a frequency of 1 Hz. The value of the elastic modulus at 25° C. is thus obtained.

Incidentally, as for the acrylic resin, the elastic modulus at 25° C. was determined based on the above method similarly to the phenoxy resin.

The average particle diameter (d50) of the inorganic filler used in each Example and Comparative Example was measured as follows.

### Measurement of Average Particle Diameter (d50)

A measurement sample was prepared by weighing 0.1 g of each of inorganic fillers used above and 9.9 g of MEK respectively, and subjecting a mixture thereof to ultrasonic dispersion treatment for 5 minutes. The average particle diameter (d50) of this measurement sample was determined from the cumulative curve of the volume fraction of the particle diameter in the particle size distribution measured by the laser diffraction scattering method (model: LMS-2000e, manufactured by Seishin Enterprise Co., Ltd.).

In each of Examples and Comparative Examples, the measurement of Young’s modulus and nanoindentation hardness, the measurement of melt viscosity, the evaluation of needle marks, and the evaluation of die attachability were evaluated by the following methods. The results are shown in Tables 1 and 2.

### Measurement of Young’s Modulus and Nanoindentation Hardness

Squares having a size of length 5.0 cm × width 5.0 cm were cut out from the film-like adhesive with a release film obtained in each of Examples or Comparative Examples. The cut samples in a state in which the release film had been peeled off were laminated and bonded on a stage at 70° C. by a hand roller. Thus, a test piece having a thickness of approximately 100 µm was obtained. A square having a size of 1.0 cm in longitudinal length × 1.0 cm in transversal length was cut out from this test piece, and a triangular pyramid diamond indenter (Berkovich type; 115°) was pressed into the surface of the film-like adhesive with an ultra-micro indentation hardness tester (ENT-NEXUS, manufactured by ELIONIX) at room temperature (25° C.) under the conditions of a maximum load of 10 µN, a load time of 80 seconds, a standby time of 17 seconds, and an unloading time of 80 seconds, and measurement was performed. The Young’s modulus and the nanoindentation hardness were determined from the Poisson’s ratio of each sample. Although bonding was performed at 70° C. at the time of preparing the test piece, the curing reaction of the epoxy resin does not substantially occur even when the test piece is exposed to 70° C. for the short time. Therefore, the above measurement results are substantially the same as the results using the film-like adhesive that is not exposed to a temperature of 25° C. or higher.

### Measurement of Melt Viscosity

Squares having a size of length 5.0 cm × width 5.0 cm were cut out from the film-like adhesive with a release film obtained in each of Examples or Comparative Examples. The cut samples in a state in which the release film had been peeled off were laminated and bonded on a stage at 70° C. by a hand roller. Thus, a test piece having a thickness of approximately 1.0 mm was obtained. A change in viscosity resistance in a temperature range of 20 to 250° C. at a temperature elevation rate of 5° C./min was measured for this test piece by using a rheometer (RS6000, manufactured by Haake). The melt viscosities at 120° C. (Pa•s) were each calculated from the obtained temperature-viscosity resistance curve.

### Evaluation of Needle Marks

The film-like adhesive with a release film obtained in each of Examples and Comparative Examples was first bonded to one surface of a dummy silicon wafer (size: 8 inch, thickness: 100 µm) by using a manual laminator (trade name: FM-114, manufactured by Technovision, Inc.) at a temperature of 70° C. and a pressure of 0.3 MPa. Thereafter, the release film was peeled off from the film-like adhesive. Then, a dicing tape (trade name: K-13, manufactured by Furukawa Electric Co., Ltd.) and a dicing frame (trade name: DTF2-8-1H001, manufactured by DISCO Corporation) were bonded on a surface of the film-like adhesive opposite to the dummy silicon wafer, by using the same manual laminator at room temperature and a pressure of 0.3 MPa. Then, dicing was performed from the dummy silicon wafer side to form squares each having a size of 5 mm × 5 mm by using a dicing apparatus (trade name: DFD-6340, manufactured by DISCO Corporation) equipped with two axes of dicing blades (Z1: NBC-ZH2050 (27HEDD), manufactured by DISCO Corporation/Z2: NBC-ZH127F-SE(BC), manufactured by DISCO Corporation) to prepare a dummy chip with a film-like adhesive.

Next, the dummy chip with a film-like adhesive was picked up from the dicing tape with a die bonder (trade name: DB-800, manufactured by Hitachi High-Technologies Corporation) under the following conditions, and the state of needle marks on the film-like adhesive after pick-up was observed, and evaluation of needle marks was performed by the following evaluation. In this test, the evaluation ranks “AA” and “A” are acceptable levels.

### Pickup Conditions

4 needles, needle R 150 (µm), needle pitch 3.5 mm, push-up speed 5 mm/sec, push-up height 200 µm, pickup time 100 msec

Evaluation criteria
AA: No needle mark was observed on the surface of the film-like adhesive in all of the 24 picked-up semiconductor chips.
A: Needle marks were observed on the surface of the film-like adhesive in 1 to 3 of the 24 picked-up semiconductor chips, and the number of needle marks on the surface of the film-like adhesive in which the needle marks were observed was 1 to 3.
B: Needle marks were observed on the surface of the film-like adhesive in 1 to 3 of the 24 picked-up semiconductor chips, and the number of needle marks on the surface of the film-like adhesive in which the needle marks were observed was 4.
C: Needle marks were observed on the surface of the film-like adhesive in 4 or more of the 24 picked-up semiconductor chips.

### Die Attachability Evaluation

The film-like adhesive with a release film obtained in each of Examples and Comparative Examples was first bonded to one surface of a dummy silicon wafer (size: 8 inch, thickness: 100 µm) by using a manual laminator (trade name: FM-114, manufactured by Technovision, Inc.) at a temperature of 70° C. and a pressure of 0.3 MPa. Thereafter, the release film was peeled off from the film-like adhesive. Then, a dicing tape (trade name: K-13, manufactured by Furukawa Electric Co., Ltd.) and a dicing frame (trade name: DTF2-8-1H001, manufactured by DISCO Corporation) were bonded on a surface of the film-like adhesive opposite to the dummy silicon wafer, by using the same manual laminator at room temperature and a pressure of 0.3 MPa. Then, dicing was performed from the dummy silicon wafer side to form squares each having a size of 10 mm × 10 mm by using a dicing apparatus (trade name: DFD-6340, manufactured by DISCO Corporation) equipped with two axes of dicing blades (Z1: NBC-ZH2050 (27HEDD), manufactured by DISCO Corporation/Z2: NBC-ZH127F-SE(BC), manufactured by DISCO Corporation) to prepare a dummy chip with a film-like adhesive.

Next, the dummy chip with a film-like adhesive was picked up from the dicing tape by using a die bonder (trade name: DB-800, manufactured by Hitachi High-Tech Corporation). Then, the film-like adhesive side of the dummy chip with a film-like adhesive was thermocompression bonded to the mounting surface side of a lead frame substrate (42Alloy-based, manufactured by Toppan Printing Co., Ltd.) under a condition of a temperature of 120° C., a pressure of 0.1 MPa (load: 400 gf) for 1.0 seconds. Here, the mounting surface of the lead frame substrate is a metal surface having a slight surface roughness.

The presence of voids at the interface between the film-like adhesive and the mounting surface of the lead frame substrate was observed for the dummy chip with a film-like adhesive which has been thermocompression bonded on the substrate, by using a ultrasonic testing apparatus (SAT) (FS300111, manufactured by Hitachi Power Solutions Co., Ltd.). Then, evaluation of the die attachability was performed based on the following criteria. In this test, the evaluation rank “A” is an acceptable level.

Evaluation criteria
A: No void was observed in all the 24 dummy chips mounted.
B: Voids were observed in 1 or more and 3 or less of the 24 dummy chips mounted.
C: Voids were observed in 4 or more of the 24 dummy chips mounted.

TABLE 1

| Level | | | Example | | | | | |
|---|---|---|---|---|---|---|---|---|
| | | | 1 | 2 | 3 | 4 | 5 | 6 |
| Adhesive layer [Parts by mass] | Epoxy resin | EPPN-501H (Triphenylmethane-type epoxy resin) | 56 | 56 | 56 | 56 | 56 | 56 |
| | | YD-128 (Bis A type epoxy resin) | 49 | 49 | 49 | 49 | 49 | 49 |
| | Phenoxy resin | YP-50 (Bis A type phenoxy resin, Tg 84° C., elastic modulus 1700 MPa) | 30 | 30 | 30 | – | – | 44 |
| | | YP-70 (Bis A/Bis F copolymer type phenoxy resin, Tg 70° C., elastic modulus 1400 MPa) | – | – | – | 30 | – | – |
| | | FX-310 (Low elasticity high-heat resistant phenoxy resin, Tg 110° C., elastic modulus 500 MPa) | – | – | – | – | 30 | – |
| | Inorganic filler | AO 502 (Alumina, average particle diameter (d50): 0.6 µm, Mohs hardness: 9 Mohs) | 55 | 320 | 480 | 320 | 320 | 350 |
| | | AG-4-8F (Silver, average particle diameter (d50): 2.0 µm, Mohs hardness: 2 Mohs) | – | – | – | – | – | – |
| | | SO-25R (Silica, average particle diameter (d50): 0.5 µm, Mohs hardness: 7 Mohs) | – | – | – | – | – | – |
| | | RY-200 (Nanosilica, average particle diameter (d50): 12 nm, Mohs hardness: 7 Mohs) | – | – | – | – | – | – |
| | | MSP-SN05 (Silicone filler, average particle diameter (d50): 0.5 µm, Mohs hardness: 1 Mohs or less) | – | – | – | – | – | – |
| | | FB-7SDS (Silica, average particle diameter (d50): 5.4 µm, Mohs hardness: 7 Mohs) | – | – | – | – | – | – |
| | S-510 (Epoxysilane-type silane coupling agent) | | 3.0 | 3.0 | 3.0 | 3.0 | 3.0 | 3.0 |
| | 2PHZ-PW (Imidazole-based curing agent) | | 8.5 | 8.5 | 8.5 | 8.5 | 8.5 | 8.5 |
| | Total solid content | | 201 | 466 | 626 | 466 | 466 | 510 |
| | Filling amount of inorganic filler [vol%] | | 10% | 40% | 50% | 40% | 40% | 40% |
| Amount of phenoxy resin/(amount of epoxy resin + amount of phenoxy resin) (wt%) | | | 22% | 22% | 22% | 22% | 22% | 30% |
| Young’s modulus (MPa) @25° C. | | | 300 | 1300 | 1800 | 1100 | 900 | 1500 |
| Nanoindentation hardness (MPa) @ 25° C. | | | 0.36 | 1.56 | 1.92 | 1.32 | 1.21 | 1.82 |
| Melt viscosity @ 120° C. (Pas) | | | 300 | 8600 | 9000 | 4800 | 9150 | 9500 |

TABLE 1 (Continued 1)

| Level | | | Example | | | | | |
|---|---|---|---|---|---|---|---|---|
| | | | 7 | 8 | 9 | 10 | 11 | 12 |
| Adhesive layer [Parts by mass] | Epoxy resin | EPPN-501H (Triphenylmethane-type epoxy resin) | 56 | 56 | 56 | 56 | 56 | 56 |
| | | YD-128 (Bis A type epoxy resin) | 49 | 49 | 49 | 49 | 49 | 49 |
| | Phenoxy resin | YP-50 (Bis A type phenoxy resin, Tg 84° C., elastic modulus 1700 MPa) | 70 | 50 | 50 | 50 | 30 | 30 |
| | | YP-70 (Bis A/Bis F copolymer type phenoxy resin, Tg 70° C., elastic modulus 1400 MPa) | – | – | – | – | – | – |
| | | FX-310 (Low elasticity high-heat resistant phenoxy resin, Tg 110° C., elastic modulus 500 MPa) | – | – | – | – | – | – |
| | Inorganic filler | AO 502 (Alumina, average particle diameter (d50): 0.6 µm, Mohs hardness: 9 Mohs) | 400 | – | – | – | – | – |
| | | AG-4-8F (Silver, average particle diameter (d50): 2.0 µm, Mohs hardness: 2 Mohs) | – | 360 | 610 | 950 | – | – |
| | | SO-25R (Silica, average particle diameter (d50): 0.5 µm, Mohs hardness: 7 Mohs) | – | – | – | – | 14 | 67 |
| | | RY-200 (Nanosilica, average particle diameter (d50): 12 nm, Mohs hardness: 7 Mohs) | – | – | – | – | – | – |
| | | MSP-SN05 (Silicone filler, average particle diameter (d50): 0.5 µm, Mohs hardness: 1 Mohs or less) | – | – | – | – | – | – |
| | | FB-7SDS (Silica, average particle diameter (d50): 5.4 µm, Mohs hardness: 7 Mohs) | – | – | – | – | – | – |
| | S-510 (Epoxysilane-type silane coupling agent) | | 3.0 | 3.0 | 3.0 | 3.0 | 3.0 | 3.0 |
| | 2PHZ-PW (Imidazole-based curing agent) | | 8.5 | 8.5 | 8.5 | 8.5 | 8.5 | 8.5 |
| | Total solid content | | 586 | 526 | 776 | 1116 | 160 | 213 |
| | Filling amount of inorganic filler [vol%] | | 40% | 20% | 30% | 40% | 5% | 20% |
| Amount of phenoxy resin/(amount of epoxy resin + amount of phenoxy resin) (wt%) | | | 40% | 32% | 32% | 32% | 22% | 22% |
| Young’s modulus (MPa) @ 25° C. | | | 1900 | 220 | 400 | 1100 | 130 | 300 |
| Nanoindentation hardness (MPa) @ 25° C. | | | 2.10 | 0.3 | 0.62 | 0.90 | 0.18 | 0.35 |
| Melt viscosity @ 120° C. (Pas) | | | 10000 | 2040 | 7880 | 9760 | 100 | 900 |

TABLE 1 (Continued 2)

| Level | | | Example | | | | |
|---|---|---|---|---|---|---|---|
| | | | 13 | 14 | 15 | 16 | 17 |
| Adhesive layer [Parts by mass] | Epoxy resin | EPPN-501H (Triphenylmethane-type epoxy resin) | 56 | 56 | 56 | 56 | 56 |
| | | YD-128 (Bis A type epoxy resin) | 49 | 49 | 49 | 49 | 49 |
| | Phenoxy resin | YP-50 (Bis A type phenoxy resin, Tg 84° C., elastic modulus 1700 MPa) | 30 | 30 | 15 | 130 | 30 |
| | | YP-70 (Bis A/Bis F copolymer type phenoxy resin, Tg 70° C., elastic modulus 1400 MPa) | – | – | – | – | – |
| | | FX-310 (Low elasticity high-heat resistant phenoxy resin, Tg 110° C., elastic modulus 500 MPa) | – | – | – | – | – |
| | Inorganic filler | AO 502 (Alumina, average particle diameter (d50): 0.6 µm, Mohs hardness: 9 Mohs) | – | – | 55 | 55 | – |
| | | AG-4-8F (Silver, average particle diameter (d50): 2.0 µm, Mohs hardness: 2 Mohs) | – | – | – | – | – |
| | | SO-25R (Silica, average particle diameter (d50): 0.5 µm, Mohs hardness: 7 Mohs) | – | – | – | – | – |
| | | RY-200 (Nanosilica, average particle diameter (d50): 12 nm, Mohs hardness: 7 Mohs) | 14 | 67 | – | – | – |
| | | MSP-SN05 (Silicone filler, average particle diameter (d50): 0.5 µm, Mohs hardness: 1 Mohs or less) | – | – | – | – | – |
| | | FB-7SDS (Silica, average particle diameter (d50): 5.4 µm, Mohs hardness: 7 Mohs) | – | – | – | – | 30 |
| | S-510 (Epoxysilane-type silane coupling agent) | | 3.0 | 3.0 | 3.0 | 3.0 | 3.0 |
| | 2PHZ-PW (Imidazole-based curing agent) | | 8.5 | 8.5 | 8.5 | 8.5 | 8.5 |
| | Total solid content | | 160 | 213 | 186 | 301 | 176 |
| | Filling amount of inorganic filler [vol%] | | 5% | 20% | 11% | 6% | 10% |
| Amount of phenoxy resin/(amount of epoxy resin + amount of phenoxy resin) (wt%) | | | 22% | 22% | 13% | 56% | 22% |
| Young’s modulus (MPa) @ 25° C. | | | 100 | 280 | 100 | 2200 | 220 |
| Nanoindentation hardness (MPa) @ 25° C. | | | 0.10 | 0.26 | 0.22 | 1.00 | 0.34 |
| Melt viscosity @ 120° C. (Pas) | | | 900 | 9500 | 120 | 10000 | 300 |

TABLE 1(Continued 3)

| Level | Example | | | | | | | | | | | | | | | | |
|---|---|---|---|---|---|---|---|---|---|---|---|---|---|---|---|---|---|
| | 1 | 2 | 3 | 4 | 5 | 6 | 7 | 8 | 9 | 10 | 11 | 12 | 13 | 14 | 15 | 16 | 17 |
| Evaluation of needle marks | A | AA | AA | A | A | AA | AA | A | A | A | A | A | A | A | A | A | A |
| Die attachability evaluation | A | A | A | A | A | A | A | A | A | A | A | A | A | A | A | A | A |

TABLE 2

| Level | | | Comparative Example | | | | | | |
|---|---|---|---|---|---|---|---|---|---|
| | | | 1 | 2 | 3 | 4 | 5 | 6 | 7 |
| Adhesive layer [Parts by mass] | Epoxy resin | EPPN-501H (Triphenylmethane-type epoxy resin) | 56 | 56 | 56 | 56 | 56 | 56 | 56 |
| | | YD-128 (Bis A type epoxy resin) | 49 | 49 | 49 | 49 | 49 | 49 | 49 |
| | Phenoxy resin | YP-50 (Bis A type phenoxy resin, Tg 84° C., elastic modulus 1700 MPa) | 10 | 190 | – | – | – | – | – |
| | | YX-7180 (Flexible phenoxy resin, Tg 15° C., elastic modulus 200 MPa) | – | – | 10 | 190 | 30 | – | – |
| | Acrylic resin | S-2060 (Acrylic resin, Tg -23° C., elastic modulus 50 MPa) | – | – | – | – | – | 10 | 190 |
| | Inorganic filler | AO 502 (Alumina, average particle diameter (d50): 0.6 µm, Mohs hardness: 9 Mohs) | 275 | 670 | 275 | 670 | 55 | 275 | 670 |
| | | SO-25R (Silica, average particle diameter (d50): 0.5 µm, Mohs hardness: 7 Mohs) | – | – | – | – | – | – | – |
| | | MSP-SN05 (Silicone filler, average particle diameter (d50): 0.5 µm, Mohs hardness: 1 Mohs or less) | – | – | – | – | – | – | – |
| | S-510 (Epoxysilane-type silane coupling agent) | | 3.0 | 3.0 | 3.0 | 3.0 | 3.0 | 3.0 | 3.0 |
| | 2PHZ-PW (Imidazole-based curing agent) | | 8.5 | 8.5 | 8.5 | 8.5 | 8.5 | 8.5 | 8.5 |
| | Total solid content | | 401 | 976 | 401 | 976 | 201 | 401 | 976 |
| | Filling amount of inorganic filler [vol%] | | 40% | 40% | 40% | 40% | 10% | 40% | 40% |
| Phenoxy resin amount/(epoxy resin amount + phenoxy resin amount) * (wt%) | | | 9% | 65% | 9% | 65% | 22% | 9% | 65% |
| Young’s modulus (MPa) @ 25° C. | | | 700 | 2400 | 400 | 1450 | 80 | 230 | 750 |
| Nanoindentation hardness (MPa) @ 25° C. | | | 0.85 | 2.32 | 0.55 | 1.56 | 0.09 | 0.35 | 1.10 |
| Melt viscosity @ 120° C. (Pas) | | | 4300 | 36000 | 1900 | 17500 | 90 | 20000 | 110000 |

TABLE 2 (Continued1)

| Level | | | Comparative Example | | | | | | |
|---|---|---|---|---|---|---|---|---|---|
| | | | 8 | 9 | 10 | 11 | 12 | 13 | 14 |
| Adhesive layer [Parts by mass] | Epoxy resin | EPPN-501H (Triphenylmethane-type epoxy resin) | 56 | 56 | 50 | 56 | 56 | 56 | 56 |
| | | YD-128 (Bis A type epoxy resin) | 49 | 49 | – | 49 | 49 | 49 | 49 |
| | Phenoxy resin | YP-50 (Bis A type phenoxy resin, Tg 84° C., elastic modulus 1700 MPa) | – | – | 100 | 30 | 30 | 30 | 30 |
| | | YX-7180 (Flexible phenoxy resin, Tg 15° C., elastic modulus 200 MPa) | – | – | – | – | – | – | – |
| | Acrylic resin | S-2060 (Acrylic resin, Tg -23° C., elastic modulus 50 MPa) | 400 | 30 | – | – | – | – | – |
| | Inorganic filler | AO 502 (Alumina, average particle diameter (d50): 0.6 µm, Mohs hardness: 9 Mohs) | 55 | 55 | 450 | – | – | – | – |
| | | SO-25R (Silica, average particle diameter (d50): 0.5 µm, Mohs hardness: 7 Mohs) | – | – | – | – | – | – | – |
| | | MSP-SN05 (Silicone filler, average particle diameter (d50): 0.5 µm, Mohs hardness: 1 Mohs or less) | – | – | – | 8 | 95 | 220 | – |
| | S-510 (Epoxysilane-type silane coupling agent) | | 3.0 | 3.0 | 7.0 | 3.0 | 3.0 | 3.0 | 3.0 |
| | 2PHZ-PW (Imidazole-based curing agent) | | 8.5 | 8.5 | 8.5 | 8.5 | 8.5 | 8.5 | 8.5 |
| | Total solid content | | 571 | 201 | 616 | 154 | 241 | 366 | 146 |
| | Filling amount of inorganic filler [vol%] | | 3% | 10% | 45% | 5% | 40% | 60% | 0% |
| Phenoxy resin amount/(epoxy resin amount + phenoxy resin amount) * (wt%) | | | 79% | 22% | 67% | 22% | 22% | 22% | 22% |
| Young’s modulus (MPa) @ 25° C. | | | 1300 | 430 | 2450 | 330 | 340 | 350 | 90 |
| Nanoindentation hardness (MPa) @ 25° C. | | | 1.90 | 0.67 | 2.35 | 0.07 | 0.07 | 0.08 | 0.12 |
| Melt viscosity @ 120° C. (Pas) | | | 110000 | 45000 | 37500 | 250 | 5600 | 12000 | 80 |

| Level | Comparative Example | | | | | | | | | | | | | |
|---|---|---|---|---|---|---|---|---|---|---|---|---|---|---|
| | 1 | 2 | 3 | 4 | 5 | 6 | 7 | 8 | 9 | 10 | 11 | 12 | 13 | 14 |
| Evaluation of needle marks | B | AA | C | AA | C | C | A | A | A | AA | B | B | B | C |
| Die attachability evaluation | B | B | C | B | C | C | C | C | C | B | B | B | C | B |

### Notes of Tables

The symbol “-” in the row of the adhesive layer means not containing the corresponding component.

*In Comparative Examples 5 to 9, the amount of the acrylic resin/(the amount of the epoxy resin + the amount of the acrylic resin) is shown.
Bis A type epoxy resin: bisphenol A type epoxy resin
Bis A type phenoxy resin: bisphenol A type phenoxy resin
Bis A/Bis F copolymerized phenoxy resin: bisphenol A/F copolymerized phenoxy resin
The “elastic modulus” in the column of phenoxy resin means “normal temperature (25° C.) elastic modulus”.

The following is clear from Tables 1 and 2.

In any of the film-like adhesives obtained using the adhesive composition that does not satisfy any of the composition, the proportion of the phenoxy resin, the Young’s modulus, and the nanoindentation hardness specified in the present invention, either the needle mark evaluation or the die attachability evaluation fails, and the suppression of the jig mark and the improvement of the die attachability cannot be achieved.

On the other hand, the film-like adhesives obtained using the adhesive composition of Examples 1 to 17 of the present invention hardly left a jig mark, and were also excellent in die attachability.

The present invention has been described as related to the present embodiments. It is our intention that the present invention not be limited by any of the details of the description unless otherwise specified, but rather be construed broadly within its spirit and scope as set out in the attached claims.

### DESCRIPTION OF SYMBOLS

| | |
|---|---|
| 1 | Semiconductor wafer |
| 2 | Adhesive layer (film-like adhesive) |
| 3 | Dicing tape |
| 4 | Semiconductor chip |
| 5 | Semiconductor chip with a film-like adhesive |
| 6 | Wiring board |
| 7 | Bonding wire |
| 8 | Sealing resin |
| 9 | Semiconductor package |

1. An adhesive composition, comprising:
an epoxy resin (A);
an epoxy resin curing agent (B);
a phenoxy resin (C); and
an inorganic filler (D),
wherein the phenoxy resin (C) has an elastic modulus of 500 MPa or more at 25° C., wherein a proportion of the phenoxy resin (C) in a total content of the epoxy resin (A) and the phenoxy resin (C) is 10 to 60 mass%, and wherein a nanoindentation hardness at 25° C. of a film-like adhesive before curing formed using the adhesive composition is 0.10 MPa or more, and the Young’s modulus at 25° C. of a film-like adhesive before curing formed using the adhesive composition is 100 MPa or more.

2. The adhesive composition according to claim 1,
wherein the inorganic filler (D) has an average particle diameter (d50) of 0.01 to 5.0 µm, and
wherein a proportion of the inorganic filler (D) in a total content of the epoxy resin (A), the epoxy resin curing agent (B), the phenoxy resin (C), and the inorganic filler (D) is 5 to 70 vol%.

3. The adhesive composition according to claim 2, wherein the inorganic filler (D) contains an inorganic filler having a Mohs hardness of 2 or more.

4. The adhesive composition according to claim 1, wherein when a film-like adhesive before curing formed using the adhesive composition is heated at a temperature elevation rate of 5° C./min from 25° C., a melt viscosity at 120° C. is in a range of 100 to 10000 Pa·s.

5. A film-like adhesive obtained from the adhesive composition according to claim 1.

6. The film-like adhesive according to claim 5, which has a thickness of 1 to 60 µm.

7. A method of producing a semiconductor package, comprising:
a first step of providing an adhesive layer by thermocompression bonding the film-like adhesive according to claim 5 to a back surface of a semiconductor wafer in which at least one semiconductor circuit is formed on a surface, and providing a dicing tape with the adhesive layer interposed between the back surface and the dicing tape;
a second step of dicing the semiconductor wafer and the adhesive layer simultaneously to obtain a semiconductor chip with an adhesive layer, the semiconductor chip with an adhesive layer including the semiconductor wafer and the adhesive layer on the dicing tape;
a third step of removing the dicing tape from the adhesive layer and thermocompression bonding the semiconductor chip with an adhesive layer and a wiring board with the adhesive layer; and a fourth step of thermally curing the adhesive layer.

8. A semiconductor package wherein a semiconductor chip and a wiring board, or semiconductor chips are bonded with a thermally curable component of the film-like adhesive according to claim 5.
